(19) United States
(12) Patent Application Publication
(10) Pub. No.: US 2025/0323631 A1
(43) Pub. Date: Oct. 16, 2025

(54) METHODS AND APPARATUSES RELATING TO HYBRID MULTI-BIT FLIP-FLOPS

(71) Applicant: Advanced Micro Devices, Inc., Santa Clara, CA (US)

(72) Inventors: Partha Pratim Ghosh, Santa Clara, CA (US); Pratap Kumar Das, Santa Clara, CA (US)

(73) Assignee: Advanced Micro Devices, Inc., Santa Clara, CA (US)

(21) Appl. No.: 17/945,984

(22) Filed: Sep. 15, 2022

(51) Int. Cl. H03K 3/037; G06F 30/394; H03K 3/012; H03K 19/17736

(52) U.S. Cl. CPC H03K 3/037; G06F 30/394; H03K 3/012; H03K 19/1774

(57) ABSTRACT

A method for constructing hybrid multi-bit flip-flops can include (i) configuring a first single-bit flip-flop in a first architectural configuration, (ii) configuring a second single-bit flip-flop in a second architectural configuration that is distinct from the first architectural configuration of the first single-bit flip-flop, and (iii) connecting the first single-bit flip-flop and the second single-bit flip-flop to form a hybrid multi-bit flip-flop.

### BACKGROUND

Within modern electronic devices, computing processors can use a multitude of flip-flops or latches as part of performing logical computations. Nevertheless, the use of such flip-flops or latches may have disadvantages, as further discussed below.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 shows a flow diagram for an example method relating to hybrid multi-bit flip-flops.

FIG. 2 shows a logical diagram comparing single-bit flip-flops and multi-bit flip-flops.

FIG. 3 shows a diagram comparing counts of inverters between single-bit flip-flops and multi-bit flip-flops.

FIG. 4 shows a conceptual diagram of different variations of hybrid multi-bit flip-flops.

FIGS. 5-6 show a schematic diagram for a high-performance single-bit flip-flop.

FIGS. 7-8 show a schematic diagram for an area-compact single-bit flip-flop.

FIG. 9 shows a schematic diagram for another example of a high-performance single-bit flip-flop.

FIG. 10 shows a logical diagram for an example of a clock network within a hybrid multi-bit flip-flop with a one bit high performance single-bit flip-flop.

FIG. 11 shows another logical diagram for a different example of a clock network within a hybrid multi-bit flip-flop with a one bit high performance single-bit flip-flop with an early clock connected to a slave latch.

FIG. 12 shows a logical diagram for an example of a clock network within a hybrid multi-bit flip-flop with a clock delay architecture.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The application discloses a flexible hybrid multi-bit flip-flop architecture for low power and high-performance applications. In this architecture, several different single-bit flip-flops can be merged together to form a multi-bit flip-flop for better area and timing, while nevertheless preserving the power consumption close to that of a standard uniform architecture.

During engineering change order (ECO) procedures when building a chip at a place-and-route (PNR) stage, if the corresponding design heavily uses multi-bit flip-flops (MBFFs), such as designs where 90% of flip-flops are formed within MBFFs, then sometimes the ECO procedures can involve replacing a single bit to satisfy a timing specification. In related solutions, replacing the single bit can be achieved by debanking the MBFF containing the single bit, and then replacing all of the related flip-flops with single-bit flip-flops (SBFFs). Nevertheless, this procedure of replacing the single bit by performing debanking of the MBFF is highly disruptive. For example, the debanking procedure involves rebuilding the clock tree in configuration with the new single-bit flip-flops. Additionally, the affected silicon real estate can be too congested, which can result in the debanking procedure involving operations that are more intensive and disruptive than otherwise.

Several modern chip designs are facing this problem. In such cases, it would be desirable, and easier, to replace a standard uniform MBFF with a hybrid version. As discussed further below, the hybrid version of the MBFF (which is formed of SBFFs having substantially different architectures, configurations, performance qualities, or sizes, for example) can have minimal area impact and close to no impact on the clock tree when used to perform the single bit substitution instead of traditional debanking. Usage of the hybrid MBFF to avoid the disruptive debanking procedure would result in a significant boost in improvement to the current design flows practices in this field.

In summary, the related solution of ripping cells out and debanking MBFFs into multiple SBFFs is undesirable because it is highly disruptive. Additionally, the traditional debanking approach also features a significant area and power penalty. In contrast, the hybrid MBFF of this application features different kinds or configurations of SBFFs that can be flexibly merged together to optimize for timing and performance, while avoiding the disruption, area penalty, and power penalty that are associated with the related. In other words, a single MBFF can feature different variants of SBFFs, thereby enabling MBFFs of different shapes, sizes, and performance ratings to be flexibly constructed and placed, rather than ripping out cells and debanking entire MBFFs into SBFFs. The hybrid architecture is flexible because there might be no restriction on the particular or on the number of different SBFFs that are used to build the corresponding MBFF.

The hybrid MBFF has multiple advantages. The design is flexible where existing or other SBFFs can be merged together to create a hybrid structure. The hybrid design can have a minimal penalty in terms of area. Similarly the hybrid design can have close to zero penalty in terms of power (e.g., clock power). The corresponding cell for this design can be used in ECO stages, which is the last stage in a PNR design and therefore the cell can help in reducing turnaround time for a design to close or finish. Moreover, the hybrid design can be technology agnostic, as discussed further below. Furthermore, the hybrid design as described herein can encompass all relevant variations and thereby correspond to a unique solution to the problem of debanking through ECO timing fixes.

A method for constructing hybrid multi-bit flip-flops can include configuring a first single-bit flip-flop in a first architectural configuration, configuring a second single-bit flip-flop in a second architectural configuration that is distinct from the first architectural configuration of the first single-bit flip-flop, and connecting the first single-bit flip-flop and the second single-bit flip-flop to form a hybrid multi-bit flip-flop.

In some examples, the hybrid multi-bit flip-flop consumes power at substantially equal to or less than a uniform multi-bit flip-flop.

In some examples, the hybrid multi-bit flip-flop uses a clock path that is substantially the same as for a uniform multi-bit flip-flop.

In some examples, the method further includes placing the multi-bit flip-flop such that a timing specification is satisfied.

In some examples, placing the multi-bit flip-flop satisfies the timing specification while bypassing a procedure for debanking a uniform multi-bit flip-flop into single-bit flip-flops.

In some examples, placing the multi-bit flip-flop is performed during a place-and-route design stage.

In some examples, the hybrid multi-bit flip-flop is formed of 2×N single-bit flip-flops where N is a natural number.

In some examples, the first architectural configuration includes a high-performance architectural configuration that features a latency between a clock signal and a data pin below a predetermined threshold.

In some examples, the first architectural configuration includes a compact area architectural configuration that is substantially smaller in area size than the high-performance architectural configuration.

In some examples, the first architectural configuration includes a clock delay configuration.

In some examples, a hybrid multi-bit flip-flop can include a first single-bit flip-flop having a first architectural configuration and a second single-bit flip-flop that is connected to the first single-bit flip-flop and that has a second architectural configuration that is distinct from the first architectural configuration.

In some examples, a semiconductor device can include a first single-bit flip-flop having a first architectural configuration and a second single-bit flip-flop that is connected to the first single-bit flip-flop to form a hybrid multi-bit flip-flop and that has a second architectural configuration that is distinct from the first architectural configuration. The hybrid multi-bit flip-flop can be configured within a processor of the semiconductor device to perform computation for the semiconductor device.

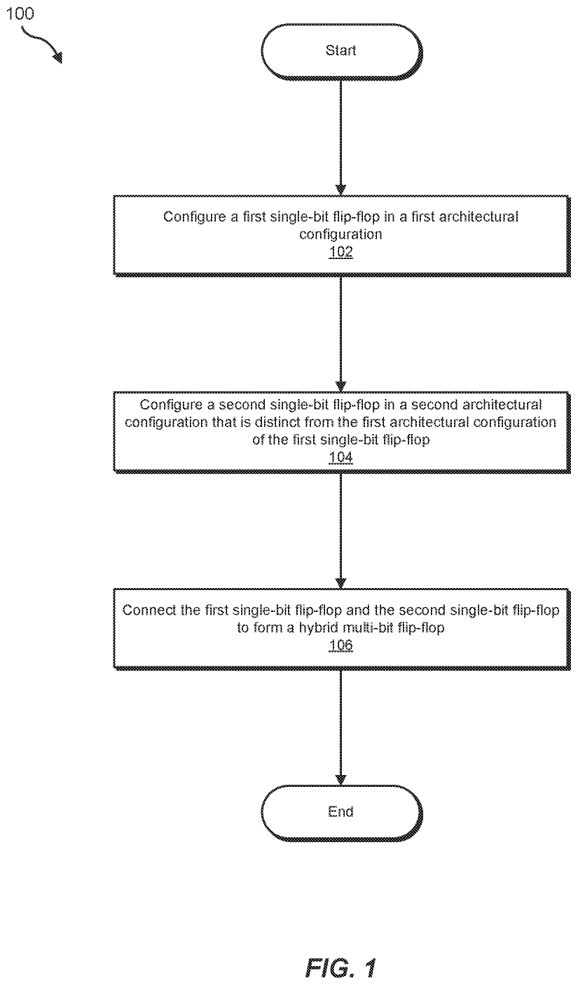

FIG. 1 shows an example flow diagram for a method 100 relating to a hybrid multi-bit flip-flop. The steps of method 100 can be performed by any suitable system, apparatus, or facility (e.g., a semiconductor manufacturing facility).

At step 102, one or more of the systems described herein can configure a first single-bit flip-flop in a first architectural configuration. For example, a semiconductor device or other electronic component manufacturing facility can configure a first single-bit flip-flop into a first architectural configuration. As another example, method 100 may operate on a field-programmable gate array or may be performed by providing an integrated circuit design with the flip-flop of step 102.

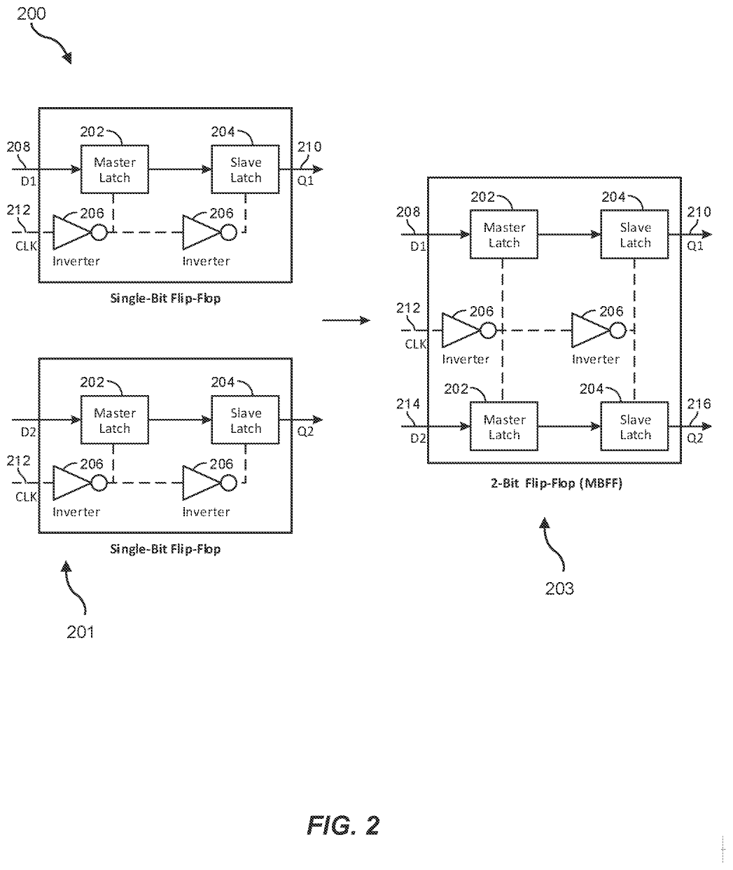

As used herein, the term single-bit flip-flop can generally refer to a circuit or an electronic logical component that stores a single bit of information in one of either of two stable states (e.g., high or low, one or zero). For purposes of the background discussion, and by way of illustrative example, FIG. 2 shows an example single-bit flip-flop 200 and an example single-bit flip-flop 201. Although flip-flops can be formed in a variety of configurations, the single-bit flip-flops of FIG. 2 can correspond to master-slave “D” flip-flops that transition state on the positive edge of the clock input signal 212, for example. Thus, the output signal 210 can track the D1 input signal 208 consistent with clock input signal 212. Single-bit flip-flop 201 has an essentially identical configuration, as further shown within FIG. 2. Note additionally that, although the terms “flip-flop” and “latch” are sometimes used to refer to substantially overlapping functionality, there can be subtle or important detailed differences between the two and, for example, flip-flops can be formed from laches, as further shown in FIG. 2. In particular, this figure illustrates how single-bit flip-flop 200 can be formed at least in part from a master latch 202 and a slave latch 204. Moreover, FIG. 2 also further illustrates how the other instances of flip-flop, single-bit flip-flop 201, is formed of a master latch 202 and a slave latch 204 in an essentially parallel configuration.

In addition to master latch 202 and slave latch 204, representative single-bit flip-flop 200 of FIG. 2 also includes two instances of an inverter 206. Another difference between a latch and a flip-flop is that a latch is generally level triggered, whereas a flip-flop is edge triggered, as understood by those having skill in the art. Accordingly, transitions between states within a single-bit flip-flop will generally be performed at the rising or falling edge of clock input signal 212. Moreover, the performance of the single-bit flip-flop will generally involve the implementation of two different instances of an inverter 206, as further illustrated within FIG. 2.

The two instances of clock input signal 212 and the two pairs of instances of inverter 206 within single-bit flip-flop 200 and single-bit flip-flop 201 indicate a level of redundancy between these two single-bit flip-flops. Accordingly, those having skill in the art can attempt to ameliorate this redundancy by creating a multi-bit flip-flop in which the functional equivalent of two single-bit flip-flops are combined in a manner such that they share clock input signal 212 and furthermore share two instances of inverter 206, as shown in the 2-bit flip-flop or multi-bit flip-flop 203 that is further shown in FIG. 2, and which further includes a D2 signal input 214 and a Q2 signal output 216.

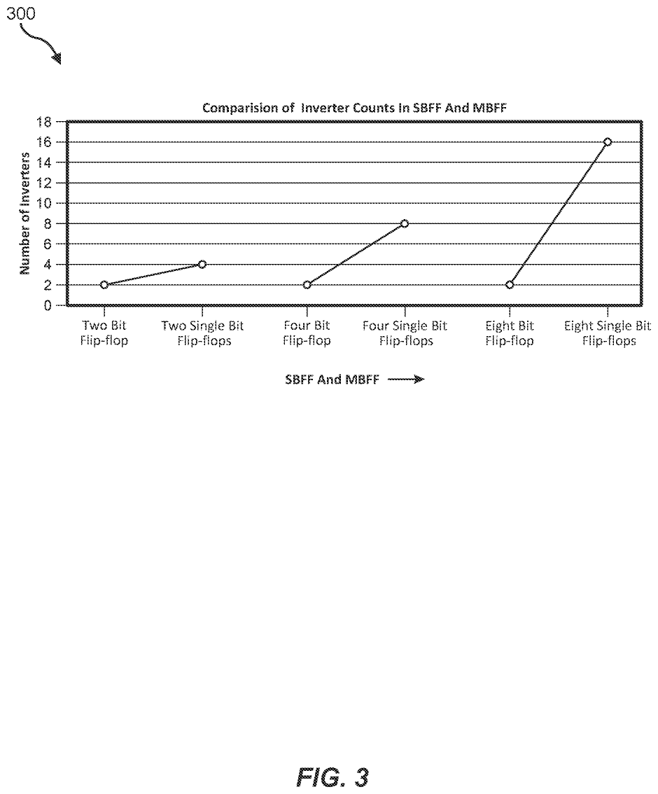

Moreover, FIG. 3 further highlights within chart 300 how any particular multi-bit flip-flop might only involve two instances of inverter 206, whereas a total number of inverters in the clock path within the flip-flops can grow exponentially to achieve the same functionality as the multi-bit flip-flop using separate and respective single-bit flip-flops. As one illustrative example, an eight bit multi-bit flip-flop might only involve two separate instances of inverter 206, whereas the same functionality implemented within eight separate single-bit flip-flops might involve 16 separate instances of inverter 206. In other words, FIG. 3 further highlights how the use of multi-bit flip-flops can be attractive by dramatically reducing the number of inverters and corresponding complexity.

Returning to step 102, the phrase “first configuration” in “configure a first single-bit flip-flop in a first architectural configuration” may refer to the fact that different single-bit flip-flops can have different architectural configurations, as discussed further below. Moreover, the standard practice in the related art is for multi-bit flip-flops to use uniformly a same architectural configuration, whereas this application discloses a “hybrid” configuration for a multi-bit flip-flop that is flexible and that helps to address the debanking problem that is further outlined at length above.

As used herein, the term “architectural configuration” generally refers to a configuration for a flip-flop that specifies metrics beyond the input-to-output logical performance of the flip-flop and, instead, additionally specifies metrics in terms of the size, shape, and performance of the flip-flop, where the performance can be measured in terms of expense (e.g., a more expensive inverter), speed (e.g., a faster switching flip-flop), or reliability (e.g., a more expensive and reliable material or brand used to make one flip-flop in comparison to another). Furthermore, the term “architectural configuration” can also refer to the specification of metrics that go beyond the external logical table or performance of the flip-flop (e.g., in terms of input and output signals), and instead further specifies internal logical arrangements or configurations that themselves differ, even if the logical table for the inputs and outputs for the flip-flop remain the same. In other words, different internal logical configurations (e.g., where some are much more complex or redundant than others) can nevertheless produce the same or substantially the same logical performance in terms of inputs and outputs, when those internal logical configurations are treated as flip-flop black boxes, for example.

Returning to method 100, at step 104 one or more of the systems disclosed herein can configure a second single-bit flip-flop in a second architectural configuration that is distinct from the first architectural configuration of the first single-bit flip-flop. Thus, as further outlined above when establishing guidance on the meaning of the term “architectural configuration,” a second flip-flop that reproduces the same or substantially the same input and output logical performance as the first flip-flop can nevertheless have a different configuration in terms of size, shape, or performance, etc.

The inventive concept of this application can highlight that, although related methodologies can uniformly use the same architectural configuration for all of the flip-flops aggregated to form other multi-bit flip-flops, the improved “hybrid” multi-bit flip-flop of this application can instead flexibly mix and match different architectural configurations, which can result in a multitude of different benefits, especially when addressing the debanking problem outlined above in terms of adding or removing a single bit to satisfy timing specifications as part of an ECO procedure.

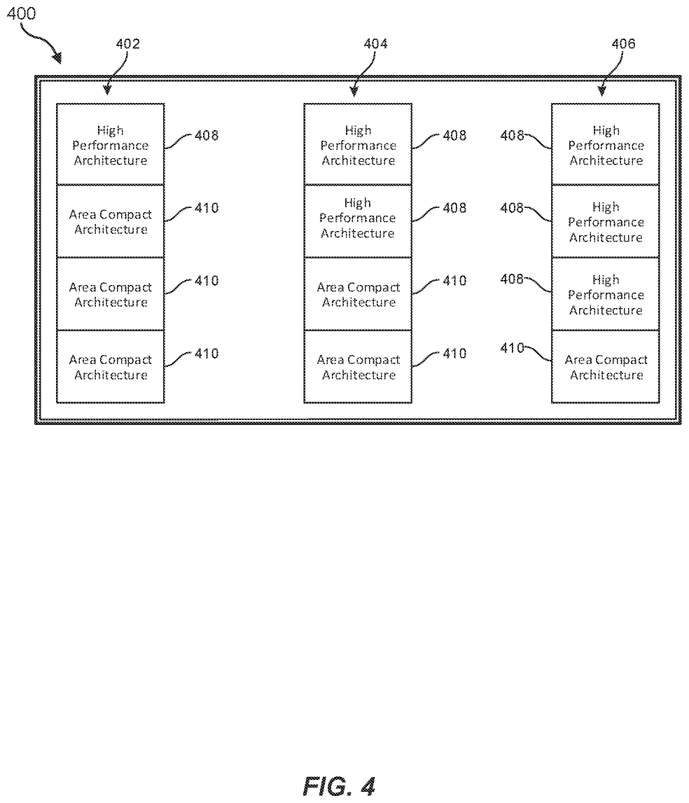

By way of illustrative example, FIG. 4 shows a block diagram 400 of the three respective variations of the hybrid architecture that is disclosed herein, in the form of a multi-bit flip-flop 402, a multi-bit flip-flop 404, and a multi-bit flip-flop 406. From a high level, the example of FIG. 4 is helpful to illustrate the benefit of multi-bit flip-flops. Usually every single-bit flip-flop comes with a clock pin, and in order for the flip-flop to work the flip-flop itself will involve a corresponding clock tree. So, for example, an individual flip-flop will involve clock buffers at one or more of entry points for each respective single-bit flip-flop. Accordingly, for related configuration based on separate and respective single-bit flip-flops, there can be hundreds of thousands of such flip-flops within any chip, or perhaps even more than that, and in that case every single respective single-bit flip-flop is going to burn power that is going into the respective entry point for that flip-flop. Thus, in applications relevant to the modern marketplace, which is heavily driven by mobile computing devices such as smartphones or tablets, the minimization of power requirements or consumption becomes particularly acute. This is especially true considering the fact that the clock tree for such single-bit flip-flops will generally always be on, and therefore the power consumption due to the clock tree is always being consumed, whether the corresponding separate single-bit flip-flops are being currently used or not.

In view of the above, related methodologies can attempt to address the power consumption dilemma by constructing uniform multi-bit flip-flops. As one illustrative example, four-bit multi-bit flip-flops are particularly attractive within related architectures, and to a lesser degree eight-bit and 16-bit multi-bit flip-flops can be implemented. Thus, in these related architectures all of the aggregated single-bit flip-flops can share the same network tree, which is also consistent with the discussion of 2-bit flip-flop 203 in connection with FIG. 2, as further outlined above. Accordingly, in the example of a four-bit multi-bit flip-flop, for separate flip-flops aggregated within the multi-bit flip-flop can together share a single clock network. By doing this, related methodologies can reduce the power consumption by a factor of approximately four. Nevertheless, this particular value can vary depending on the clock load, as understood by those having skill in the art, and therefore the average power consumption savings can be on the order of approximately 30%, which still constitutes a huge level of improvement.

The primary problem associated with the related methodologies introduced and discussed above is that these related methodologies generally use low performance architectural configurations for the respective single-bit flip-flops. Similarly, the related methodologies are uniform in the sense that the uniformly use a single architectural configuration of respective single-bit flip-flops that are embedded or aggregated within the corresponding multi-bit flip-flops. The low performance architectural configuration can be used in an attempt to conserve power and to conserve area. For example, when four instances of these low performance architectural configurations are aggregated together within a multi-bit flip-flop, each one of these low performance architectural configurations must operate at the frequency of the corresponding central processing unit, such as 3 GHz. On the other hand, even though two synchronous paths may have to perform at the same 3 GHz frequency, one path may have more logic depth than another and so one can involve a high-performance flip-flop for meeting timing specifications, whereas the other path may be relaxed as the logic depth is less and use of a low performance area compact flip-flop may suffice. Accordingly, the automated tool in a place-and-route environment, when used with these related methodologies, will try to strip the uniform multi-bit flip-flop into respective single-bit flip-flops in a debanking procedure, as first alluded to above. When this occurs, each single-bit flip-flop will again be configured with its own clock tree, and this further results in a dramatic penalty in terms of area and power (i.e., effectively reverses or undoes the area and power advantages that were obtained by using the multi-bit flip-flop in comparison to a series of respective single-bit flip-flops). In other words, after the performance of the debanking procedure, there is essentially zero savings obtained in terms of area and in terms of performance. The problem of debanking can be particularly impactful for modern high-end microchips.

To address the problem of debanking, this application discloses a general and flexible hybrid multi-bit flip-flop architecture. FIG. 4 helps to further illustrate how the hybrid multi-bit flip-flop architecture can be effectively plug-and-play and/or modular such that different blocks (as shown in the block diagram of FIG. 4) can be conveniently, or even arbitrarily, inserted or removed to create different permutations of sets of single-bit flip-flops, with varying architectural configurations, all aggregated together within hybrid multi-bit flip flops.

As further shown in block diagram 400, the different multi-bit flip-flops of this figure correspond to different variations or mixings of respective single-bit flip-flops that themselves have different architectural configurations, as further outlined above. The example of this figure focuses on the differences between two architectural configurations, which correspond to the high-performance architecture 408 and the area compact architecture 410. High-performance architecture 408 can feature a latency between a clock signal (e.g., clock input signal 212) and an input data pin D below a predetermined threshold. Moreover, area compact architecture 410 can be substantially smaller in area size than high-performance architectural configuration 408.

As further illustrated in this figure, multi-bit flip-flop 402 features an instance of a high-performance architecture 408 at the top and three separate instances of the area compact architecture 410 beneath the instance of the high-performance architecture 408. In contrast, multi-bit flip-flop 404 features two instances of the high-performance architecture 408 at the top and two instances of the area compact architecture 410 at the bottom. Lastly, multi-bit flip-flop 406 features three instances of the high-performance architecture 408 at the top and one separate instance of the area compact architecture 410 at the bottom.

The three separate multi-bit flip-flops that are shown within FIG. 4 are merely shown for illustrative purposes and do not limit the scope of disclosure here. The overall flexible hybrid architecture of this application does not necessarily correspond to one or more, or any, of the example multi-bit flip-flops that are shown in FIG. 4. For example, none of the separate multi-bit flip-flops that are shown in FIG. 4 feature an instance of one architectural configuration on both sides (i.e., the top side and the bottom side) of the other architectural configuration, and instead each of the multi-bit flip-flops features a first series of one or more of one architectural configuration followed by another series of one or more of the remaining architectural configuration. Nevertheless, the flexible hybrid architecture of this application is not so limited and, although not shown in FIG. 4, the hybrid multi-bit flip-flop can feature a varied mixture of different architectural configurations (not just two) in any suitable or desired order, as further discussed below. By way of example, the multi-bit flip-flop can feature first an instance of the high-performance architecture 408, then an instance of the area compact architecture 410, and then another instance of the high-performance architecture 408, and so on, in an interweaving fashion, because the flexible hybrid architecture is not limited to any particular order, as further outlined above. Moreover, any variation of the flexible hybrid architecture can be configured to consume power at substantially equal to or less than a uniform multi-bit flip-flop. For example, any variation of the flexible hybrid architecture can be configured to consume no more than 110% of the power of a uniform multi-bit flip-flop, except in examples of a clock delay variant, which can consume more power than the uniform multi-bit flip-flop.

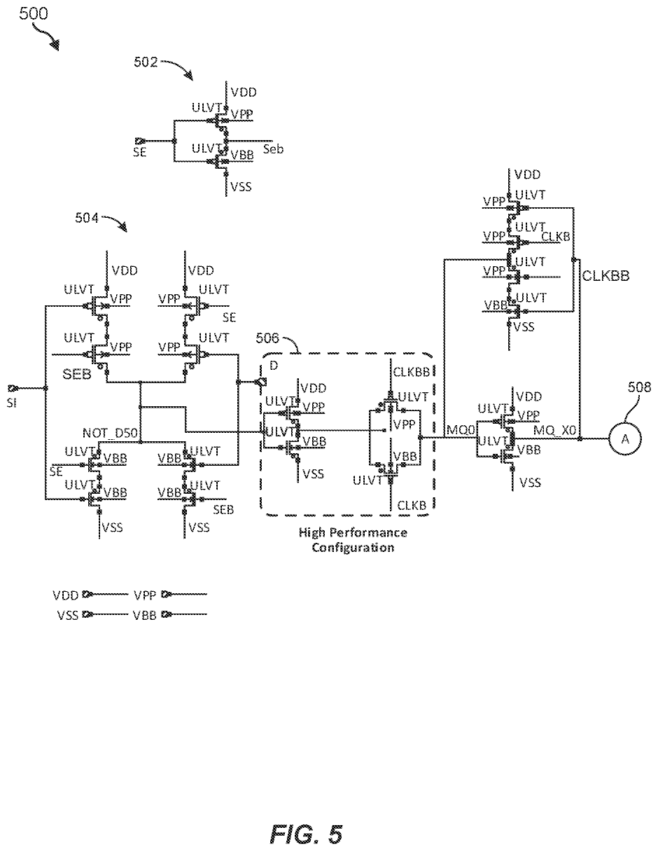

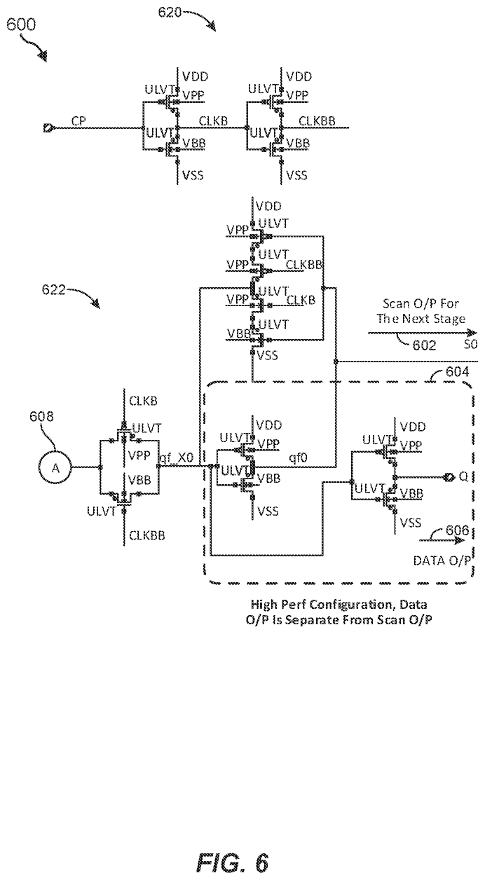

To be more specific, FIGS. 5-6 show a portion 500 and a portion 600, respectively, of a schematic diagram of the high-performance architecture 408. In particular, a high-performance configuration 506 in FIG. 5 and another high-performance configuration 604 in FIG. 6 can be embedded within portion 500 and portion 600, respectively. Furthermore, portion 500 and portion 600 can be connected between FIG. 5 and FIG. 6 across a connection indicator 508 in FIG. 5 and a corresponding connection indicator 608 in FIG. 6. Portion 500 can further include a flip-flop circuit 504 in which high-performance configuration 506 is embedded. Similarly, portion 600 can further include a flip-flop circuit 622 in which high-performance configuration 604 is further embedded, as well as a clock circuit 620 that can provide a clock network for flip-flop circuit 504 and flip-flop circuit 622. High-performance configuration 506 and high-performance configuration 604 can together connect to form a high-performance architectural configuration corresponding to high-performance architecture 408, for example.

As further illustrated within FIG. 6, clock circuit 0622 (i.e., a clock tree) can be composed of one inverter in combination with another instance of the inverter. As further discussed above, in the example of a series of separate and respective single-bit flip-flops, each one of these respective single-bit flip-flops would involve or require its own respective clock circuit 622 (i.e., its own pair of inverters). So in the example of a four-bit series of single-bit flip-flops, eight separate inverters would be used (see also FIGS. 2-3). In contrast, the hybrid multi-bit flip-flop of FIGS. 5-8 instead use a single instance of clock circuit 622.

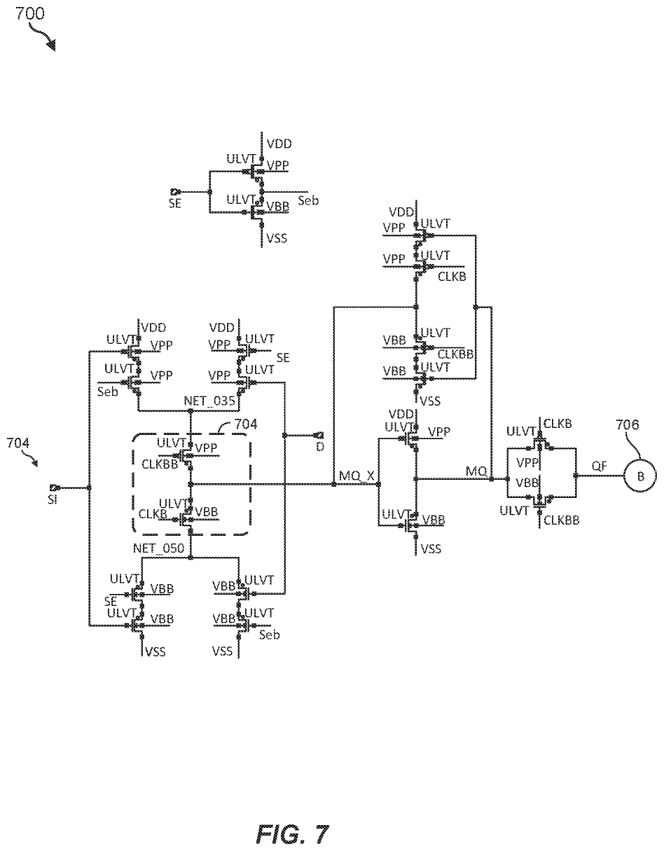

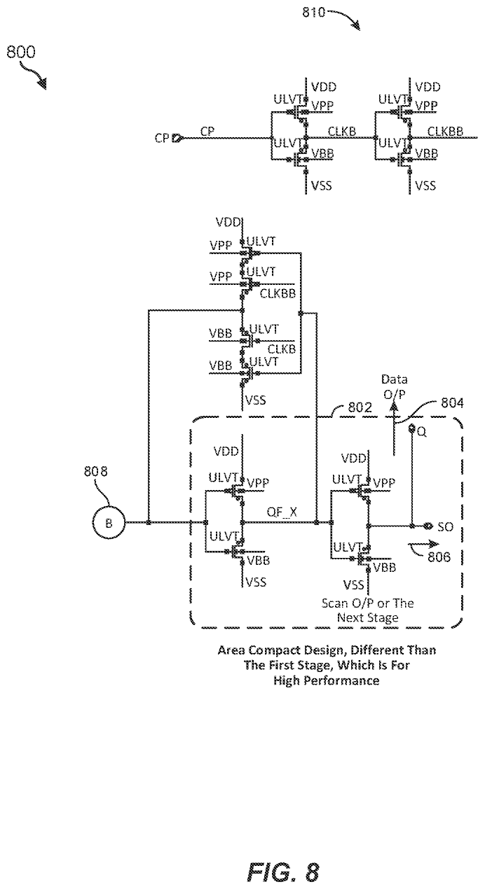

Similarly, FIG. 7-8 show a portion 700 and a portion 800, respectively of a schematic diagram of the area compact architecture 410. In particular, an area compact design 704 in FIG. 7 and another area compact design 802 in FIG. 8 can be embedded within portion 700 and portion 800, respectively. Area compact design 704 and area compact design 802 can connect together to form an area compact architectural configuration corresponding to area compact architecture 410, for example. Furthermore, portion 700 and portion 800 can be connected between FIG. 7 and FIG. 8 across a connection indicator 708 in FIG. 7 and a corresponding connection indicator 808 in FIG. 8.

FIG. 7 further illustrates how portion 500 and portion 600 can correspond to a first stage of a hybrid multi-bit flip-flop, where the first stage contains the one instance of high-performance architecture 408. Similarly, portion 700 and portion 800 (including a clock network 810) can correspond to a second stage of the same hybrid multi-bit where the second stage contains the one instance of area compact configuration 410, as further discussed above, and as shown in detail within illustrative FIGS. 5-8.

In particular, FIGS. 5-6 further illustrate how, within the high-performance configuration, the data path and the scan path have been separated to obtain performance improvements. Thus, the signal line corresponding to indicator 602 and the signal line corresponding to indicator 606 have been separated within high-performance configuration 604. Accordingly, the high-performance configuration of FIGS. 5-6 can use a smaller capacitor while nevertheless being associated with greater speed, and the high-performance configuration of FIGS. 5-6 can be advantageous in terms of lower power consumption as well. And this lower power consumption can be due to the fact that, during functional activity, the scan portion is not using the function data output pin of the flip-flop, thereby resulting in a smaller load capacitor.

In contrast, the signal line corresponding to indicator 804 and the signal line corresponding to indicator 806 within the area compact design 802 of FIG. 8 are effectively combined, thereby resulting in a reduction of area or real estate consumption. Nevertheless, the area compact design 802 achieves this reduction in size only by incurring a penalty in terms of more capacitance and more delay, where the greater capacitance translates to more power consumption during a functional mode.

Returning to method 100, at step 106 or more of the systems described herein can connect the first single-bit flip-flop and the second single-bit flip-flop to form a hybrid multi-bit flip-flop. For example, a semiconductor or other electronic component manufacturing facility can connect the first single-bit flip-flop and the second single-bit flip-flop to form the hybrid multi-bit flip-flop. Thus, in the example of FIG. 4, various instances of high-performance architecture 408 can be connected to various instances of area compact architecture 410, as further discussed at length above.

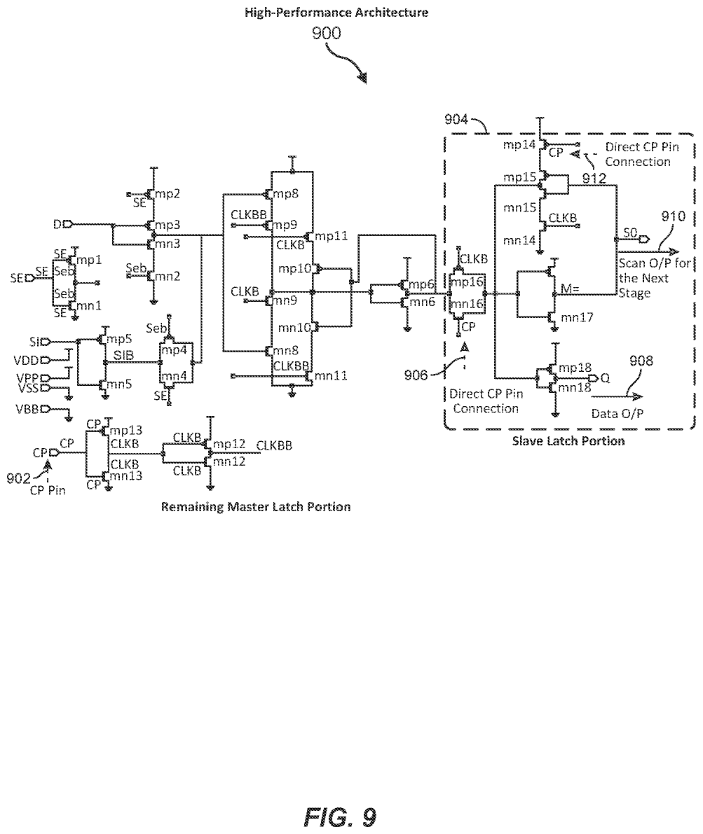

Returning to the more detailed examples of FIGS. 5-8, FIG. 6 further illustrates how a signal line corresponding to indicator 602 can provide scanning output for the second stage (i.e., FIGS. 7-8) of the hybrid multi-bit flip-flop of FIGS. 5-8. Similarly, a signal line corresponding to indicator 606 can provide data output for the second stage (i.e., FIGS. 7-8) of the hybrid multi-bit flip-flop of FIGS. 5-8. Accordingly, returning to FIG. 7, the same signal line corresponding to indicator 602 is further continued as a signal line corresponding to indicator 704 (SI), which is appropriately connected to portion 700 in which area compact design 704 is embedded, as further discussed above. Moreover, area compact design 802 also further illustrates how a signal line corresponding to indicator 804 can provide data output to an additional or further stage of the hybrid multi-bit flip flop (e.g., a third stage). Similarly, area compact design 802 also further illustrates how a signal line corresponding to indicator 806 can further provide scanning output, which can facilitate an additional stage of the multi-bit flip-flop. In this manner, any suitable permutation of different architectural configurations of single-bit flip-flops may be mixed and matched, or otherwise combined, in a modular fashion, to build various varied permutations of hybrid multi-bit flip-flops, consistent with the examples of FIGS. 4-8, as well as the example of FIG. 9, which is further discussed below.

For completeness, FIG. 9 shows another schematic diagram for a high-performance architecture 900 for an example of a different implementation of the high-performance architecture (similar to, but distinct from, FIGS. 5-6). As further shown in this figure, an input clock signal may be provided at an input pin 902, as well as a direct input pin connection 906 and a direct input pin connection 912. Similarly, a slave latch portion 904 may provide a data output 908 and a scan output 910 for a next stage of the corresponding hybrid multi-bit flip-flop. Slave latch portion 904 in combination with the remaining master latch portion together form high-performance architecture 900. Moreover, in this distinct implementation of the high-performance single-bit flip-flop architecture, an instance of the architecture can form the first, first and second, or first, second and third stages of the corresponding hybrid multi-bit flip-flop.

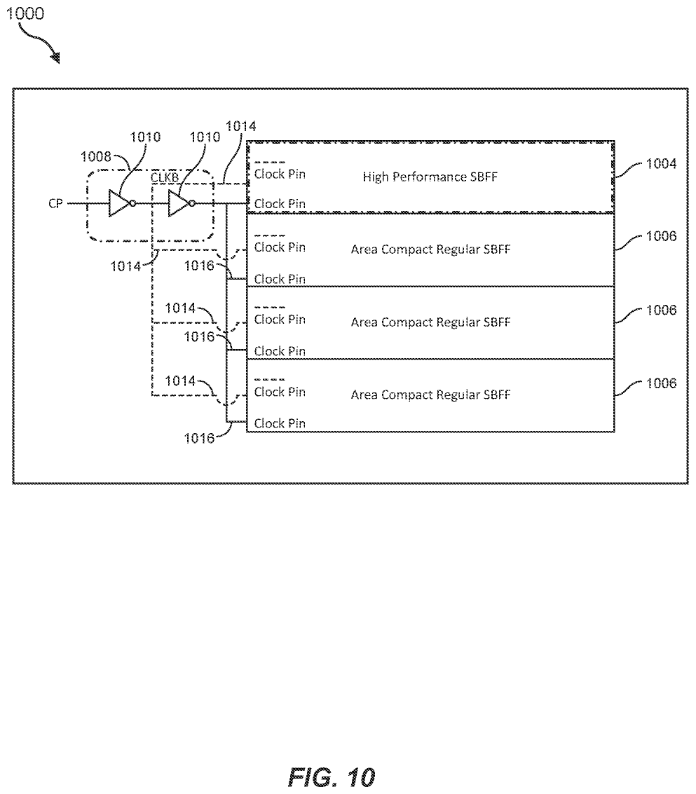

Returning again to the context of FIG. 4, FIG. 10 provides more detail of a setup 1000 regarding how multi-bit flip-flop 402 may be implemented. Example setup 1000 can feature a multi-bit flip-flop that is formed of an instance of high-performance architecture 408 at the top, which corresponds to a high-performance single-bit flip-flop 1004 and further corresponds to the high-performance architecture of FIGS. 5-6 and/or 9 (for example), followed by a series of three instances of area compact configuration 410, which correspond to an area compact regular single-bit flip-flop 1006, as further shown in this figure. Moreover, setup 1000 can also further feature a clock pin signal 1016, as well as an inverted clock pin signal 1014, where the difference between clock pin signal 1016 and inverted clock pin signal 1014 is due to an instance of inverter 1010 that is disposed as the rightward instance of inverter 1010 within pair 1008 of such inverters. Pair 1008 of inverters are further shown as receiving an input signal as the generator for the corresponding clock signal. Pair 1008 corresponds to a clock network that is shared by all stages of the corresponding hybrid multi-bit flip-flop. Moreover, in some examples, the hybrid multi-bit flip-flop is formed of 2×N single-bit flip-flops where N is a natural number, such as 4 in the examples of FIG. 4, although 3-bit and other odd or varying numbers of whole numbers can also be used.

With respect to FIG. 10, and generally speaking, any variation of the flexible hybrid architecture can be configured to use a clock path that is substantially the same as for a uniform multi-bit flip-flop. Moreover, this ability to use substantially the same clock path as for the uniform multi-bit flip-flop presents a dramatic and significant improvement upon the debanking procedure of the related art, because this procedure involves ripping out cells and replacing a uniform multi-bit flip-flop with a series of respective single-bit flip-flops, which cannot use the same clock path, and therefore the reconfiguration or reconstruction of one or more clock paths contributes significantly to the disruption and complications that are associated with the disadvantages of the related art.

With respect to high-performance single-bit flip-flop 1004, this corresponds to a configuration whereby the single-bit flip-flop has been skewed to create a delay. The skewing to create the delay is performed due to the fact that, within these environments, everything travels through physical gates such as inverters. In certain cases, a timing specification might not be satisfied, such as a 3 GHz frequency specification. According to such a specification, all of the electric current within the device must pass through all designated gates or inverters consistent with the 3 GHz frequency timing. Nevertheless, sometimes satisfying such a specification can involve manipulating or adjusting either the clock signal and/or the data signal (e.g., within modern “synchronized chips” where clock signal and data signal are the predominant factors controlled as part of the design process). One such example manipulation might correspond to the delaying the arrival of the clock signal. In this scenario, even though the data from the data signal is moving slower than the timing specification would otherwise involve, the clock signal has been pushed such that the timing specification would be satisfied earlier.

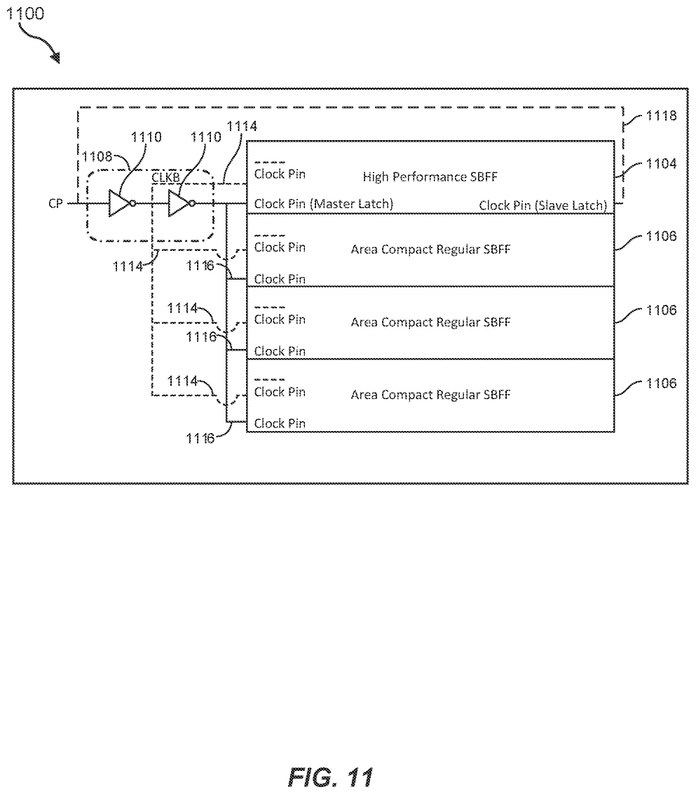

FIG. 11 shows another setup 1100 corresponding to a different implementation of a hybrid multi-bit flip-flop featuring high-performance single-bit flip-flop 1104. In this figure, the reference numerals essentially parallel those in FIG. 10. Nevertheless, setup 1100 differs from setup 1000 by having a distinct clocking scheme. In particular, setup 1100 may be implemented with the different embodiment of the high-performance single-bit flip-flop shown in FIG. 9, as further discussed above. In this second clocking scheme, the clock network is shared by all of the stages of the corresponding hybrid multi-bit flip-flop, but the early clock from the CP pin is connected to the clock pin of the slave latch portion of high-performance single-bit flip-flop 1104, as further shown in FIG. 11. In contrast, an output of pair 1108 of instances of inverter 1114 is provided as an input to the clock pin corresponding to the master latch portion.

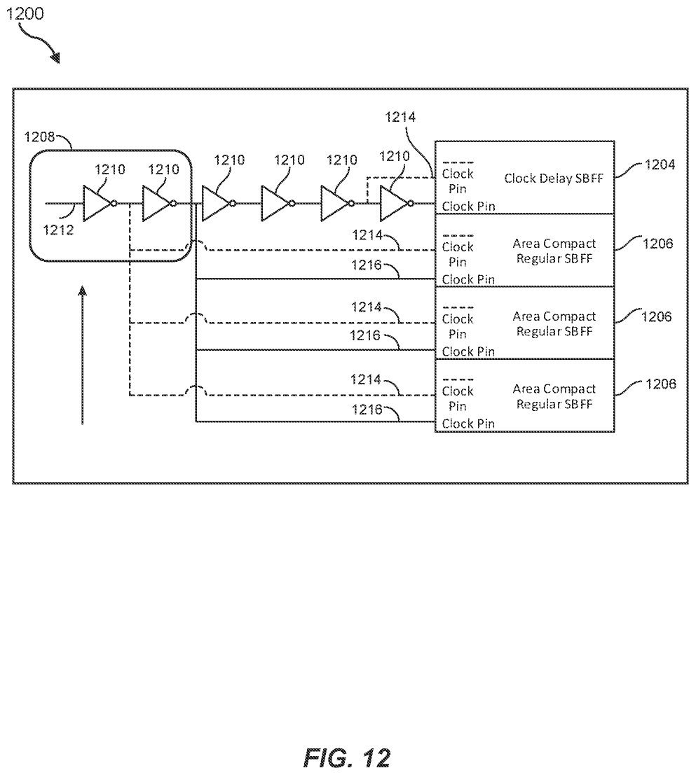

Although the examples of FIGS. 4 and 10-11 focus upon the high-performance architecture 408 and the area compact architecture 410, the flexible hybrid architecture of this application is not limited to these two particular architectural configurations, as further discussed above, and instead can encompass a wide variety or potentially unlimited number of different architectural configurations. As just one illustrative example, the reader can consider setup 1200 in FIG. 12 for a hybrid multi-bit flip-flop that features a clock delay single-bit flip-flop 1204 rather than a high-performance single-bit flip-flop. To help understand, the reader can also return to FIG. 6 and clock circuit 620. Rather than the single instance of clock circuit 620 for an entire multi-bit flip-flop, those having skill in the art could instead design a configuration whereby two separate instances of clock circuit 620 are used for the entire multi-bit flip-flop, and one of those instances of clock circuit 620 can be effectively delayed or slowed down for usage with clock delay single-bit flip-flop 1204. Thus, in FIG. 12, the four additional instances of inverter 1210 effectively delays the clock signal, which is exactly the delay consistent with functioning of the clock delay configuration of setup 1200. In contrast, the remaining instances of area compact regular single-bit flip-flop 1206 are connected to an output of pair 1208 of inverters 1210, which corresponds to a normal CLKB signal. Despite this hybrid mixture of delayed and not-delayed clock paths, the hybrid multi-bit flip-flop nevertheless functions properly, and there is still a substantial overlap or sharing of the clock tree, and still a substantial reduction in the number of inverters that would otherwise be involved in a series of separate and respective single-bit flip-flops that are not aggregated together as part of a multi-bit flip-flop.

As further discussed above in the context of problems solved by the flexible hybrid architecture of this application, the multi-bit flip-flop can be placed or configured within a semiconductor device in a manner such that a timing specification is satisfied. In other words, during engineering change order procedures when building a chip at a place-and-route stage, the satisfaction of a timing specification can involve replacing a single bit, which can correspond to one of the single-bit flip-flops that, in function or in aggregate, form a multi-bit flip-flop. Rather than performing a disruptive and complicated debanking procedure that strips out an entire uniform multi-bit flip-flop and replaces the uniform multi-bit flip-flop with a corresponding series of single-bit flip-flops, the uniform multi-bit flip-flop can instead (at the place-and-route design stage) be modified to form, or can be replaced with, an example of the hybrid multi-bit flip-flop of this application without the cost in terms of disruption and complication that is associated with debanking. In this manner, the same single bit can be effectively replaced, thereby satisfying the timing specification, while bypassing the procedure for debanking the uniform multi-bit flip-flop into single-bit flip-flops.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A method for constructing hybrid multi-bit flip-flops, the method comprising:
configuring a first single-bit flip-flop in a first architectural configuration;
configuring a second single-bit flip-flop in a second architectural configuration that is distinct from the first architectural configuration of the first single-bit flip-flop; and
connecting the first single-bit flip-flop and the second single-bit flip-flop to form a hybrid multi-bit flip-flop.

2. The method of claim 1, wherein the hybrid multi-bit flip-flop consumes power at substantially equal to or less than a uniform multi-bit flip-flop.

3. The method of claim 1, wherein the hybrid multi-bit flip-flop uses a clock path that is substantially the same as for a uniform multi-bit flip-flop.

4. The method of claim 1, further comprising placing the multi-bit flip-flop such that a timing specification is satisfied.

5. The method of claim 4, wherein placing the multi-bit flip-flop satisfies the timing specification while bypassing a procedure for debanking a uniform multi-bit flip-flop into single-bit flip-flops.

6. The method of claim 4, wherein placing the multi-bit flip-flop is performed during a place-and-route design stage.

7. The method of claim 1, wherein the hybrid multi-bit flip-flop is formed of 2×N single-bit flip-flops where N is a natural number.

8. The method of claim 1, wherein the first architectural configuration comprises a high-performance architectural configuration that features a latency between a clock signal and a data pin below a predetermined threshold.

9. The method of claim 8, wherein the first architectural configuration comprises a compact area architectural configuration that is substantially smaller in area size than the high-performance architectural configuration.

10. The method of claim 1, wherein the first architectural configuration comprises a clock delay configuration.

11. A hybrid multi-bit flip-flop comprising:
a first single-bit flip-flop having a first architectural configuration; and
a second single-bit flip-flop that is connected to the first single-bit flip-flop and that has a second architectural configuration that is distinct from the first architectural configuration.

12. The hybrid multi-bit flip-flop of claim 11, wherein the hybrid multi-bit flip-flop consumes power at substantially equal to or less than a uniform multi-bit flip-flop.

13. The hybrid multi-bit flip-flop of claim 11, wherein the hybrid multi-bit flip-flop uses a clock path that is substantially the same as for a uniform multi-bit flip-flop.

14. The hybrid multi-bit flip-flop of claim 11, wherein the multi-bit flip-flop is placed within a semiconductor device such that a timing specification is satisfied.

15. The hybrid multi-bit flip-flop of claim 14, wherein the multi-bit flip-flop was placed within the semiconductor device while bypassing a procedure for debanking a uniform multi-bit flip-flop into single-bit flip-flops.

16. The hybrid multi-bit flip-flop of claim 14, wherein placing the multi-bit flip-flop was performed during a place-and-route design stage.

17. The hybrid multi-bit flip-flop of claim 11, wherein the hybrid multi-bit flip-flop is formed of 2×N single-bit flip-flops where N is a natural number.

18. The hybrid multi-bit flip-flop of claim 11, wherein the first architectural configuration comprises a high-performance architectural configuration that features a latency between a clock signal and a data pin below a predetermined threshold.

19. The hybrid multi-bit flip-flop of claim 18, wherein the second architectural configuration comprises a compact area architectural configuration that is substantially smaller in area size than the high-performance architectural configuration.

20. A semiconductor device comprising:
a first single-bit flip-flop having a first architectural configuration;
a second single-bit flip-flop that is connected to the first single-bit flip-flop to form a hybrid multi-bit flip-flop and that has a second architectural configuration that is distinct from the first architectural configuration; and
the hybrid multi-bit flip-flop is configured within a processor of the semiconductor device to perform computation for the semiconductor device.
